(19) United States
(12) Patent Application Publication
(10) Pub. No.: US 2010/0026141 A1
(43) Pub. Date: Feb. 4, 2010

(54) INTRACAVITY ULTRASONIC PROBE

(75) Inventor: Atsushi OSAWA, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/507,469

(22) Filed: Jul. 22, 2009

(30) Foreign Application Priority Data
Jul. 30, 2008 (JP) 2008-196291

(51) Int. Cl. H01L 41/053; G10K 9/122

(52) U.S. Cl. 310/335; 310/340

(57) ABSTRACT

An intracavity ultrasonic probe which prevents or reduces degradation or failures with time due to use of an intermediate balloon made of rubber. The intracavity ultrasonic probe includes: a piezoelectric vibrator having a piezoelectric material, and a first electrode layer and a second electrode layer formed on a first surface and a second surface of the piezoelectric material, respectively; at least one acoustic matching layer provided above the second electrode layer; an acoustic lens disposed above the at least one acoustic matching layer so as to cover the at least one acoustic matching layer and the piezoelectric vibrator; and a sulfur adsorbing material layer disposed between the acoustic lens and the second electrode layer.

### CROSS-REFERENCE TO RELATED APPLICATION

The present application claims priority from Japanese Patent Application No. 2008-196291 filed on Jul. 30, 2008, the contents of which are incorporated herein by reference in their entirety.

### BACKGROUND OF THE INVENTION

1. Field of the Invention

The present invention relates to an ultrasonic probe to be used for intracavity examination in an ultrasonic endoscope or the like, and in particular, relates to a structure for preventing corrosion of an electrode of a piezoelectric vibrator of an intracavity ultrasonic probe.

2. Description of a Related Art

Ultrasonic imaging is an image generation technology utilizing the nature of ultrasonic waves that the ultrasonic waves are reflected at a boundary between regions with different acoustic impedances. The ultrasonic imaging for acquiring internal information of an object to be inspected by transmitting and receiving ultrasonic waves has been utilized in a wide range of departments including not only the fetal diagnosis in the obstetrics, but also gynecology, circulatory system, digestive system, and so on, as a safe imaging technology because the ultrasonic imaging enables image observation in real time and accompanies no exposure to radiation unlike radiography or the like.

As the ultrasonic transducer for transmitting and receiving ultrasonic waves, a vibrator (piezoelectric vibrator) having electrodes formed on both sides of a material exhibiting a piezoelectric effect (piezoelectric material) is usually used. As the piezoelectric material, a piezoelectric ceramic represented by PZT (Pb (lead) zirconate titanate), a polymer piezoelectric material represented by PVDF (polyvinylidene fluoride), and so on are used.

When a voltage is applied between the electrodes of such a vibrator, the piezoelectric material expands and contracts due to the piezoelectric effect and generates ultrasonic waves. Furthermore, a plurality of vibrators is one-dimensionally or two-dimensionally arranged and driven by a plurality of driving signals with a predetermined delay given thereto, and thereby, an ultrasonic beam can be formed toward a desired direction. On the other hand, the vibrators expand and contract by receiving propagating ultrasonic waves and generate electric signals. These electric signals are used as reception signals of the ultrasonic waves.

FIG. 6 is a partially-cutaway perspective view schematically showing a conventional ultrasonic probe. A plurality of vibrators 102 arranged in the azimuth direction is housed in a housing (case) 105, and lead wires from the electrodes of the vibrator 102 are connected to a cable (shielded cable), thereby constituting an ultrasonic probe 100.

On the back face of the vibrator 102, a backing material 101 is disposed in order to absorb unnecessary ultrasonic waves. Each of the vibrators 102 includes an individual electrode 102a formed on the backing material 101, a piezoelectric material 102b formed on the individual electrode 102a, and a common electrode 102c formed on the piezoelectric material 102b. Usually, the common electrodes 102c of the plurality of vibrators are connected in common to the earth potential (GND). On the other hand, the individual electrodes 102a of the plurality of vibrators are connected to cables (shielded cables) via printed wirings formed in two FPCs (flexible printed circuit boards) respectively fixed to an upper surface and a lower surface of the backing material 101, for example, and furthermore, are connected to an electronic circuit within an ultrasonic diagnosis apparatus main body via the cables. The electrodes 102a and 102c of the vibrator 102 are often made of silver.

Further, in the case of a piezoelectric vibrator employing a piezoelectric ceramic as the piezoelectric material, there is a large difference between the acoustic impedance of the vibrator 102 and the acoustic impedance of a human body or the like, and reflection of ultrasonic waves will occur at the boundary surface therebetween, resulting in a propagation loss. Therefore, at least one acoustic matching layer (FIG. 6 shows two acoustic matching layers 103a and 103b) is disposed on a front face of the vibrator 102. Furthermore, in order to focus ultrasonic waves in the elevation direction perpendicular to the arrangement direction of the plurality of vibrators 102 (the azimuth direction), an acoustic lens 104 is disposed above the acoustic matching layer 103b.

Here, the acoustic impedance is a constant inherent to a substance and represented by a product of the density of an acoustic medium and the acoustic velocity in the acoustic medium, and as its unit, MRayl (mega Rayl) is usually used, where 1 Mrayl=1×10⁶ kg·m⁻²·s⁻¹. The acoustic impedance of a typical piezoelectric ceramic is approximately 25 MRayl to approximately 35 MRayl, and the acoustic impedance of a human body is approximately 1.5 MRayl.

As the acoustic lens 104, an acoustic lens is usually used which is formed to have a convex shape toward the outside, i.e., a Quonset hut-like shape by employing a material such as silicon rubber having an acoustic impedance nearly equal to that of a human body and having an acoustic velocity value smaller than that within a human body. The acoustic velocity value within a human body is almost equal to that in water, i.e., approximately 1500 m/s, while the acoustic velocity value in silicon rubber is approximately 800 m/s to 1000 m/s.

Usually, an ultrasonic diagnosing apparatus includes a body-surface ultrasonic probe to be used in contact with an object to be inspected or an intracavity ultrasonic probe to be used by being inserted into a body cavity of the object. Furthermore, in recent years, an ultrasonic endoscope as a combination of an endoscope for optically observing the interior of the object and an intracavity ultrasonic probe has been used frequently. As the intracavity ultrasonic probe, a convex-type probe having strip-shaped piezoelectric vibrators arranged in the shape of an arched bridge in the minor axis direction (the azimuth direction), a radial-type probe having strip-shaped piezoelectric vibrators circularly arranged in the azimuth direction, and a linear array-type probe having strip-shaped piezoelectric vibrators linearly arranged in the azimuth direction are enumerated.

FIG. 7 is a cross sectional view schematically showing a use state of a conventional intracavity ultrasonic probe. In the case of using an intracavity ultrasonic probe 100 within the body such as a digestive organ or a bronchus, if there is an air gap in the propagation path of ultrasonic waves, the propagation capability of ultrasonic waves will decrease significantly, thereby making the measurement difficult. Therefore, a balloon made of rubber (hereinafter, referred to as an intermediate balloon) 200 is attached to the probe tip part, and the intermediate balloon 200 is filled with liquid 210 such as water to expand the intermediate balloon 200, and then, ultrasonic imaging is performed in a state where the intermediate balloon 200 is in contact with a digestive organ wall or a bronchial wall. Thus, an ultrasonic image can be acquired through the liquid 210 within the intermediate balloon 200. Since ultrasonic waves hardly propagate in the air, such an intermediate balloon 200 and the liquid 210 such as water to fill the intermediate balloon 200 are needed to successfully acquire ultrasonic images.

However, the balloon for forming the intermediate balloon 200 is made of rubber, and the vulcanization is performed in manufacturing the balloon, and thereby, the interior or surface of the rubber contains sulfur. Accordingly, in the case of using the ultrasonic probe 100 in a body cavity, a sulfur component (sulfur ion or the like) 220 which is a component contained in the intermediate balloon 200 will elute when the intermediate balloon 200 is expanded by the liquid 210. As a result, the liquid 210 in contact with the ultrasonic probe 100 will contain the sulfur component 220.

The eluted sulfur component 220 sometimes reaches the probe main body through the acoustic lens 104 which is the outermost layer of the ultrasonic probe 100. Furthermore, the sulfur component 220 having reached the probe main body will reach the vibrator 102 through an acoustic matching layer 103. Sulfur has a very high affinity with the silver of the electrode 102c formed at the surface of the vibrator 102 and thus easily causes a sulfuration reaction to form silver sulfide. Silver sulfide is an insulating material, which causes an increase in the resistance or disconnection of the electrode 102c, resulting in a reduction in sensitivity of the element or a failure of the element. As described above, if the intracavity ultrasonic probe 100 is continued to be used for many years, the probe performance will degrade or the probe will be damaged with time.

In this regard, Japanese Patent Application Publication JP-A-10-5227 discloses a technology to be used in an intracavity ultrasonic probe for endoscope, having electrical components such as vibrators and a lead wire group incorporated in a cylindrical body. According to the technology, the electrical components are covered with a film of a high molecular compound such as a polyimide film having impermeability against the sulfur component, and thereby, a corrosion factor such as water or a sulfur molecule is prevented from entering and corroding the electrical components.

However, in the disclosed technology, the film covering the electrical components has not a small acoustic impedance and therefore has an effect of making the design of the acoustic matching layer difficult. Further, when the film is broken or holed, it is impossible to prevent water or the sulfur component from entering and corroding an electrode part.

Incidentally, if a sulfur-free balloon, which does not contain sulfur, is selected to cover the ultrasonic probe, the corrosion of a vibrator electrode due to sulfur can be suppressed. However, with the sulfur-free material instead of rubber, a thin and flexible balloon in sufficiently close contact with an organ within a body cavity cannot be formed, and therefore, the accuracy of measurement will degrade.

### SUMMARY OF THE INVENTION

The present invention has been achieved in view of such problems. A purpose of the present invention is to provide an intracavity ultrasonic probe which prevents or reduces degradation or failures with time due to use of an intermediate balloon made of rubber.

In order to accomplish the above-described purpose, an intracavity ultrasonic probe according to one aspect of the present invention comprises: a piezoelectric vibrator including a piezoelectric material, and a first electrode layer and a second electrode layer formed on a first surface and a second surface of the piezoelectric material, respectively; at least one acoustic matching layer provided above the second electrode layer; an acoustic lens disposed above the at least one acoustic matching layer so as to cover the at least one acoustic matching layer and the piezoelectric vibrator; and a sulfur adsorbing material layer disposed between the acoustic lens and the second electrode layer.

According to the one aspect of the present invention, in the intracavity ultrasonic probe to be used in an ultrasonic endoscope or the like, a sulfur component is trapped by the sulfur adsorbing material before the sulfur component dissolved in liquid within an intermediate balloon made of rubber corrodes an electrode. It is therefore possible to prevent or reduce the sulfur within the intermediate balloon from reacting with a vibrator electrode and causing degradation or failures with time, thereby extending the life of the intracavity ultrasonic probe. Further, since the intermediate balloon can be made of a flexible rubber, a highly accurate ultrasonic image can be acquired.

### BRIEF DESCRIPTION OF THE DRAWINGS

FIG. 1 is a cross sectional view schematically showing a use state of an intracavity ultrasonic probe according to a first embodiment of the present invention;

FIG. 2 is a cross sectional view schematically showing an intracavity ultrasonic probe according to a first variation of the first embodiment;

FIG. 3 is a cross sectional view schematically showing an intracavity ultrasonic probe according to a second variation of the first embodiment;

FIG. 4 is a conceptual view showing an ultrasonic probe which employs a sulfur adsorbing material layer in the first embodiment as an electromagnetic shield;

FIG. 5 is a cross sectional view schematically showing an intracavity ultrasonic probe according to a second embodiment of the present invention;

FIG. 6 is a partially-cutaway perspective view schematically showing a conventional ultrasonic probe; and

FIG. 7 is a cross sectional view schematically showing a use state of a conventional intracavity ultrasonic probe.

### DESCRIPTION OF THE PREFERRED EMBODIMENTS

Hereinafter, embodiments of the present invention will be described in detail with reference to the drawings. The same reference numerals will be assigned to the same component elements and the description thereof will be omitted.

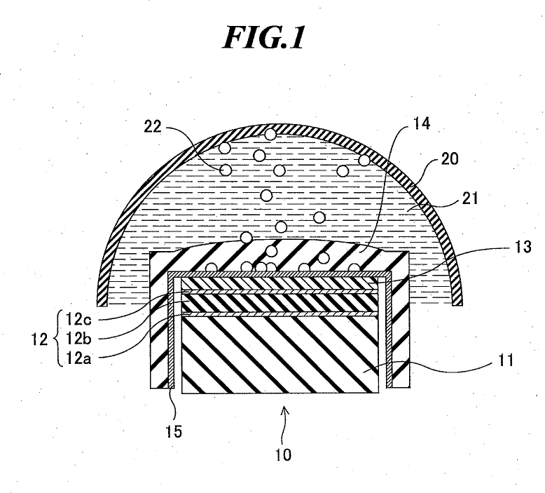

FIG. 1 is a cross sectional view schematically showing a use state of an intracavity ultrasonic probe according to a first embodiment of the present invention. This intracavity ultrasonic probe is to be used in an ultrasonic endoscope, for example. As shown in FIG. 1, an intracavity ultrasonic probe 10 includes a plurality of piezoelectric vibrators 12, at least one acoustic matching layer 13 provided above the plurality of piezoelectric vibrators 12, an acoustic lens 14 disposed above the at least one acoustic matching layer 13 so as to cover the at least one acoustic matching layer 13 and the plurality of piezoelectric vibrators 12. The plurality of piezoelectric vibrators 12 are supported by a backing material 11 formed to have a convex shape in the azimuth direction.

The backing material 11 contains a rigid material such as a hard rubber, to which an ultrasonic attenuation material, such as ferrite or ceramic, is added according to need. Above the backing material 11, the plurality of piezoelectric vibrators 12 is arranged at a predetermined pitch in a one-dimensional or two-dimensional array.

Each of the piezoelectric vibrators 12 includes a piezoelectric material 12b, an electrode layer 12a formed on a first surface (lower surface in the view) of the piezoelectric material 12b, and an electrode layer 12c formed on a second surface (upper surface in the view) of the piezoelectric material 12b. The lower electrode layer 12a facing the backing material 11 is an individual electrode to be individually connected to respective one of the plurality of piezoelectric vibrators 12, and the upper electrode layer 12c facing the acoustic matching layer 13 is a common electrode common to the plurality of piezoelectric vibrators 12. Each of the electrode layers 12a and 12c includes, for example, a palladium silver thin film, a platinum titanium thin film, a gold nickel chromium thin film, a silver paste coating film, or the like.

In order to match the acoustic impedances between the piezoelectric vibrator 12 and a human body to be measured, the acoustic matching layer 13a includes a substance having an intermediate acoustic impedance between the both impedances. The acoustic matching layer 13 often has a multilayered structure. In the case of an acoustic matching layer having two layers, an organic material such as an epoxy resin, an urethane resin, a silicon resin, or an acrylate resin is used as an outer acoustic matching layer, while a quartz glass or the above-described organic material mixed with the powder of a material, such as zirconia, tungsten, or ferrite, having a high acoustic impedance is used as an inner acoustic matching layer. In this manner, the acoustic impedances can be matched.

The acoustic lens 14 has an acoustic impedance nearly equal to that of a human body, and is made of a material, such as a silicon rubber, having an acoustic velocity value smaller than that within a human body. The acoustic lens 14 has a cross-sectional shape like a convex lens, which is thick at the center and thin at the edge, in the elevation direction perpendicular to the azimuth direction in which the plurality of piezoelectric vibrators 12 are arranged, and has an effect of focusing ultrasonic waves.

The intracavity ultrasonic probe 10 according to the first embodiment further includes a sulfur adsorbing material layer 15 between the acoustic lens 14 and the electrode layer 12c disposed under the acoustic matching layer 13. The sulfur adsorbing material layer 15 shown in FIG. 1 is obtained by forming a gold thin film in the rear surface of the acoustic lens 14 by vapor deposition or sputtering. Alternatively, the sulfur adsorbing material layer 15 may be formed by spraying nano particles, to which gold is adhered, onto the rear surface of the acoustic lens 14.

When the intracavity ultrasonic probe 10 is used within a body, an intermediate balloon 20 is attached to the probe tip part, and liquid 21 such as water is injected into the intermediate balloon 20 to expand the intermediate balloon 20. Thereby, the surface of the intermediate balloon 20 is kept in close contact with a digestive organ wall or bronchial wall as a measurement part without an air gap, and then, ultrasonic wave imaging is performed. This is because if there is an air gap in an ultrasonic wave path, the propagation of ultrasonic waves is significantly disturbed and precise imaging cannot be performed. However, when the liquid 21 is injected into the intermediate balloon 20, the sulfur contained in the rubber or adhered to the surface of the rubber will elute into the liquid 21.

Since silicon rubber used as the acoustic lens 14 passes the sulfur or the like therethrough, a part of the sulfur component (sulfur ion or the like) 22, which eluted into the liquid 21 from the rubber forming the intermediate balloon 20, will pass through the acoustic lens 14 of the ultrasonic probe 10. The sulfur component having passed through the acoustic lens 14 is captured by the sulfur adsorbing material layer 15 formed on the back side of the acoustic lens 14, and cannot further enter the inner part. Accordingly, in the case where the electrode layer 12c is made of a substance, such as silver, which will corrode to become an insulator or be disconnected due to sulfuration, it is possible to suppress electrode corrosion due to sulfur because the sulfur component 22 is blocked by the sulfur adsorbing material layer 15 and cannot reach the electrode layer 12c.

In the conventional technology, in which the electrical components are covered with a sulfur-impermeable film, such as a polyimide film, made of a material which does not pass sulfur therethrough, if the film is cracked or holed, sulfur will enter the inner part and cause damages. However, in the case where the sulfur adsorbing material layer 15 is used, even if the layer has a crack or a hole, sulfur passing through the crack or the hole would be adsorbed onto the nearby sulfur adsorbing material surface. Therefore, the amount of sulfur, which leaks into the sulfur adsorbing material layer 15 and reaches the electrode layer 12c, is limited, and thereby, the corrosion of an electrode can be suppressed and a longer life of the intracavity ultrasonic probe 10 can be achieved. The corrosion problem is more important in the common electrode 12c close to the acoustic lens 14 than in the individual electrode 12a disposed between the piezoelectric material 12b and the backing material 11.

The sulfur adsorbing material is selected from materials which cause chemical reaction with sulfur and bond thereto and materials which have a high affinity with sulfur and is unlikely to release sulfur once having captured the sulfur. Noble metals such as platinum and rhodium, and particularly, gold are effective as the sulfur adsorbing material because these metals have a special chemical affinity with sulfur. The sulfur adsorbing material layer 15 can be formed on the rear surface of the acoustic lens 14 by using various known methods, for example, by sputtering or vapor deposition or a method of spraying and fixing nano particles to which one of these metals is adhered. In order not to cause a significant effect on the propagation of ultrasonic waves, the sulfur adsorbing material layer 15 is preferably formed as a thin film having a thickness approximately equal to 1% to 5% of the ultrasonic wavelength in the material.

Although the electrode layer with a longer life is more preferable, there is little need for the electrode layer to have a life longer than the life of the apparatus. Therefore, even if the sulfur adsorbing material layer 15 is relatively thin, it functions sufficiently. Further, for example, the powder obtained by attaching gold onto the surface of a nano particle has a large surface area of the adsorption material, and therefore, the sulfur adsorbing material layer 15 having a high sulfur adsorption capability can be obtained by using this powder.

On the other hand, it is also contemplated that the sulfur adsorbing material layer is formed on the front surface of the acoustic lens 14, however, the front surface may be exposed to the outside and worn or damaged, and may excessively adsorb sulfur because the front surface is directly contacted with the liquid containing sulfur. Therefore, the sulfur adsorbing material layer formed on the front surface of the acoustic lens 14 is not preferable.

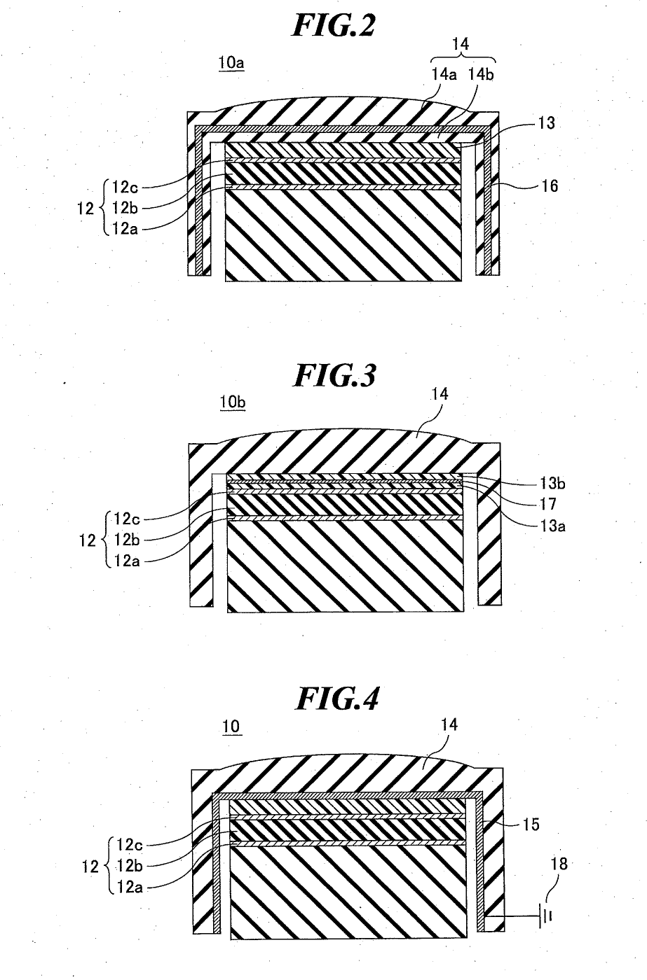

FIG. 2 is a cross sectional view schematically showing an intracavity ultrasonic probe according to a first variation of the first embodiment. An intracavity ultrasonic probe 10a according to the first variation is characterized in that the sulfur adsorbing material layer is formed within the acoustic lens, and other configurations are the same as those in the first embodiment.

The acoustic lens 14 is formed by being divided into two portions including an outer member 14a as a main body and an inner member 14b as an additional part which is inserted inside the outer member 14a. A sulfur adsorbing material layer 16 is formed on the outer surface of the inner member 14b or in the inner surface of the outer member 14a. When gold is used as the sulfur adsorbing material, the sulfur adsorbing material layer 16 is formed by depositing the sulfur adsorbing material in a thickness equal to 1% to 5% of the wavelength of an ultrasonic wave, for example, by sputtering of gold or by blasting of nano particles, to which gold is adhered.

Even if the sulfur component 22 having eluted into the liquid 21 within the intermediate balloon 20 as shown in FIG. 1 breaks into the acoustic lens 14, it is captured by the sulfur adsorbing material layer 16 formed within the acoustic lens 14 and cannot further break into the inner part. It is therefore possible to suppress corrosion of the electrode layers 12a and 12c, particularly the common electrode layer 12c, and prevent damages such as an insulation abnormality.

The sulfur adsorbing material layer 16 formed within the acoustic lens 14 advantageously has resistance against mechanical stimuli during assembly or during operation and is less susceptible to damaging because the inner member 14b serves as the protection film.

FIG. 3 is a cross sectional view schematically showing an intracavity ultrasonic probe according to a second variation of the first embodiment. An intracavity ultrasonic probe 10b according to the second variation is characterized in that the sulfur adsorbing material layer is formed between a plurality of acoustic matching layers. In the case where the plurality of acoustic matching layers (FIG. 3 shows two acoustic matching layers 13a and 13b) having a multilayered structure are used, a sulfur adsorbing material layer 17 can be formed between the plurality of acoustic matching layers. The sulfur adsorbing material layer 17 formed within the acoustic matching layers 13a and 13b is less susceptible to damaging because it is embedded into a substance.

Even if the sulfur component 22 having eluted into the liquid 21 within the intermediate balloon 20 as shown in FIG. 1 passes through the acoustic lens 14, it is captured by the sulfur adsorbing material layer 17 formed within the acoustic matching layers 13a and 13b. Accordingly, corrosion of the electrode layers 12a and 12c can be suppressed, and damages such as an insulation abnormality can be prevented.

FIG. 4 is a conceptual view showing an ultrasonic probe which employs the sulfur adsorbing material layer in the first embodiment as an electromagnetic shield. When the sulfur adsorbing material layer 15 in the intracavity ultrasonic probe as shown in FIG. 1 is made of a metal or the like and has electrical conductivity, it is possible to improve the S/N ratio by electrically connecting the sulfur adsorbing material layer 15 to an earth terminal 18 provided with an earth potential such that the sulfur adsorbing material layer 15 serves as an electromagnetic shield. Since the sulfur adsorbing material layer 15 formed of a conductive material such as gold on the back side of the acoustic lens 14 covers the piezoelectric vibrator 12 and the electrode portions thereof, the sulfur adsorbing material layer 15 serves as an electromagnetic shield for shielding the piezoelectric vibrator 12 and the electrode portions from electromagnetic induction to reduce induction noises by being grounded. The sulfur adsorbing material layer 16 formed within the acoustic lens 14 as shown in FIG. 2 also has the same function and effect by being grounded.

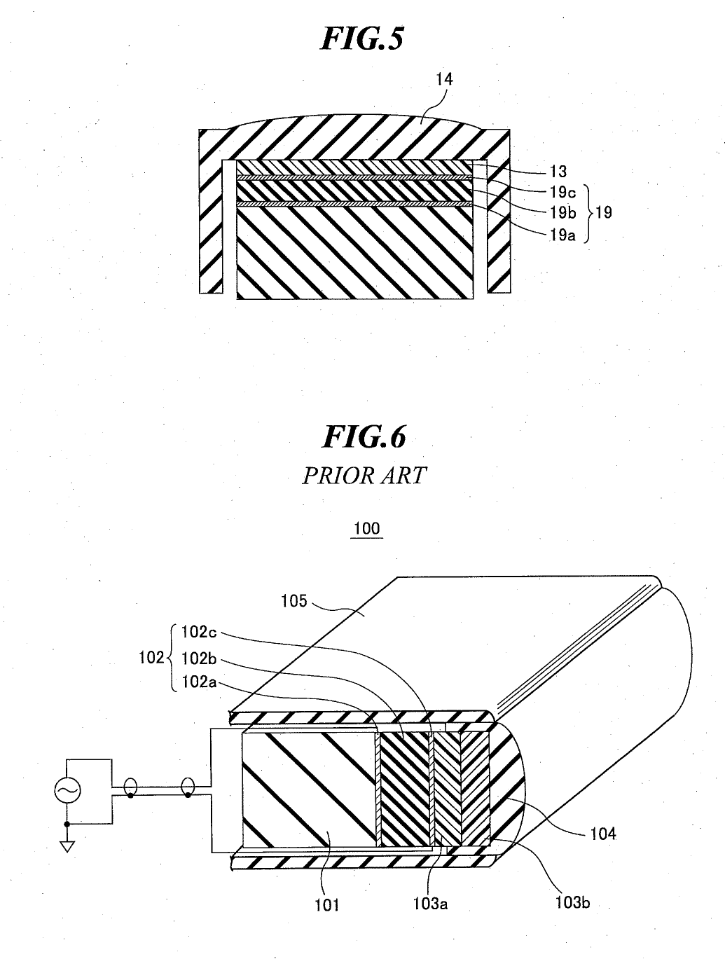

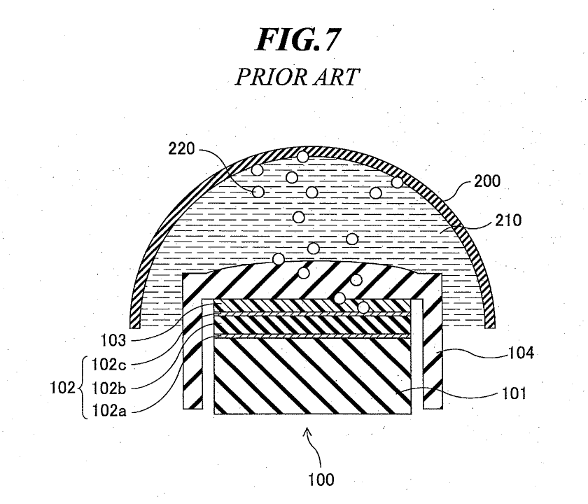

FIG. 5 is a cross sectional view schematically showing an intracavity ultrasonic probe according to a second embodiment of the present invention. The intracavity ultrasonic probe according to the second embodiment is provide with piezoelectric vibrators 19 each including a piezoelectric material 19b, and an individual electrode layer 19a and a common electrode layer 19c respectively formed on a first surface (lower surface in the view) and a second surface (upper surface in the view) of the piezoelectric material 19b. In the second embodiment, the individual electrode layer 19a and the common electrode layer 19c are made of a sulfur adsorbing material, such as gold, having an electrical conductivity so as not to receive such damages due to sulfur as in the case of a silver electrode. In this manner, the life of the intracavity ultrasonic probe is extended.

The electrode material used here is preferably a noble metal, such as gold, platinum, or rhodium, which is less likely to be corroded by sulfur. Since the entered sulfur is almost completely adsorbed by the common electrode layer 19c, there is very few amount of sulfur which further reaches the individual electrode layer 19a through the piezoelectric material 19b. For this reason, the individual electrode 19a may be made of a material containing, as a principal component, a substance such as silver which is likely to be affected by sulfur.

1. An intracavity ultrasonic probe comprising:
a piezoelectric vibrator including a piezoelectric material, and a first electrode layer and a second electrode layer formed on a first surface and a second surface of said piezoelectric material, respectively;
at least one acoustic matching layer provided above said second electrode layer;
an acoustic lens disposed above said at least one acoustic matching layer so as to cover said at least one acoustic matching layer and said piezoelectric vibrator; and
a sulfur adsorbing material layer disposed between said acoustic lens and said second electrode layer.

2. An intracavity ultrasonic probe comprising:
a piezoelectric vibrator including a piezoelectric material, and a first electrode layer and a second electrode layer formed on a first surface and a second surface of said piezoelectric material, respectively;
at least one acoustic matching layer provided on said second electrode layer;
an acoustic lens disposed on said at least one acoustic matching layer so as to cover said at least one acoustic matching layer and said piezoelectric vibrator; and
a sulfur adsorbing material layer disposed within said acoustic lens.

3. The intracavity ultrasonic probe according to claim 1, wherein said sulfur adsorbing material layer has an electrical conductivity.

4. The intracavity ultrasonic probe according to claim 2, wherein said sulfur adsorbing material layer has an electrical conductivity.

5. The intracavity ultrasonic probe according to claim 3, wherein said sulfur adsorbing material layer is electrically connected to an earth potential.

6. The intracavity ultrasonic probe according to claim 4, wherein said sulfur adsorbing material layer is electrically connected to an earth potential.

7. An intracavity ultrasonic probe comprising:
a piezoelectric vibrator including a piezoelectric material, and a first electrode layer and a second electrode layer formed on a first surface and a second surface of said piezoelectric material, respectively;
at least one acoustic matching layer provided on said second electrode layer; and
an acoustic lens disposed on said at least one acoustic matching layer so as to cover said at least one acoustic matching layer and said piezoelectric vibrator,
wherein at least said second electrode layer is formed of a sulfur adsorbing material having an electrical conductivity.

8. The intracavity ultrasonic probe according to claim 1, wherein said sulfur adsorbing material layer contains gold.

9. The intracavity ultrasonic probe according to claim 2, wherein said sulfur adsorbing material layer contains gold.

10. The intracavity ultrasonic probe according to claim 7, wherein said sulfur adsorbing material layer contains gold.
